(19) United States
(12) Patent Application Publication
(10) Pub. No.: US 2026/0188603 A1
(43) Pub. Date: Jul. 2, 2026

(54) SPLIT OBJECTIVE LENS FOR ELECTRON BEAM TO ENHANCE TOPOGRAPHICAL IMAGING

(71) Applicant: KLA Corporation, Milpitas, CA (US)

(72) Inventors: Pengnan LU, Shanghai (CN); Christopher SEARS, Fremont, CA (US)

(21) Appl. No.: 19/006,950

(22) Filed: Dec. 31, 2024

(51) Int. Cl. H01J 37/14; H01J 37/26

(52) U.S. Cl. CPC H01J 37/14; H01J 37/26; H01J 2237/1405; H01J 2237/152; H01J 2237/24475; H01J 2237/2448

(57) ABSTRACT

A system uses a split objective lens with an electron beam. The system has an electron beam source that generates an electron beam, a stage configured to hold a workpiece in a path of the electron beam, a detector that receives secondary electrons and back-scattered electrons emitted from the workpiece on the stage, and an objective lens disposed in the path of the electron beam. The objective lens includes an inner pole piece, an outer pole piece, and a coil between the inner pole piece and the outer pole piece. The inner pole piece defines a gap along the path of the electron beam.

### FIELD OF THE DISCLOSURE

This disclosure relates to an objective lens for a system that uses and electron beam.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Defect review typically involves re-detecting defects that were detected by an inspection process and generating additional information about the defects at a higher resolution using either a high magnification optical system or a scanning electron microscope (SEM). Defect review is typically performed at discrete locations on specimens where defects have been detected by inspection. The higher resolution data for the defects generated by defect review is more suitable for determining attributes of the defects such as profile, roughness, or more accurate size information.

Various architectures can be used to collect dark field (DF) electrons with a launching angle >40° while providing a high topographical contract. One is to position a detector above the workpiece, such as a semiconductor wafer, which collects the spreads dark field signals before an objective lens. This results in a relatively large working distance. Another design collects dark field signals behind the objective lens. This allows the workpiece to be immersed in the objective lens field and get a stronger focus. The dark field signals are collimated first by the lens field to pass through the long way to the detector.

In an instance, a behind lens dark field (BLDF) has five channels. One channel is in the center and the other four surround the center channel. The channels can be segmented to cover 90° of azimuth angle each. The segmented side channels can provide topographic image.

In a BLDF system, the center and side channels can both receive secondary electrons (SE) and back-scattered electrons (BSE). Secondary electron yield tends to be larger than back-scattered electrons. The collection efficiency of secondary electrons is higher than back-scattered electrons because of its lower energy. The secondary electrons also tend to be more collimated to the detector area. As a result, the grey level (e.g., image brightness) on the BLDF is dominated by secondary electrons for both center and side channels. When using secondary electrons for topographical imaging, images have the disadvantage of charging. Although there is an energy filter to select only back-scattered electrons, the low collection efficiency of back-scattered electrons makes images with a low signal-to-noise ratio. To increase back-scattered electrons on the side channels of the detector, the space along the back-scattered electrons path in the objective lens was enlarged. The objective lens had thinner pole piece and larger cone opening. To reduce secondary electrons, side channels were moved closer to lens. Secondary electrons have a smaller beam size at the entrance of a BLDF detector but larger angle afterwards. At this plane, side channels with a hole in the center would allow most secondary electrons pass to the center channel downstream. However, these changes may not apply to a compact system of objective lens and detector. New systems and methods are needed.

### BRIEF SUMMARY OF THE DISCLOSURE

A system is provided in a first embodiment. The system includes an electron beam source that generates an electron beam; a stage configured to hold a workpiece in a path of the electron beam; a detector that receives secondary electrons and back-scattered electrons emitted from the workpiece on the stage; and an objective lens disposed in the path of the electron beam. The objective lens includes an inner pole piece, an outer pole piece, and a coil between the inner pole piece and the outer pole piece. The inner pole piece defines a gap along the path of the electron beam.

The inner pole piece may be a split lens.

The inner pole piece may be configured to collimate a majority of the secondary electrons to a center channel of the detector. In an example, >95% of the secondary electrons are directed at the center channel.

The inner pole piece may be configured to collect more of the back-scattered electrons on a side channel of the detector than the secondary electrons.

The system may be an electron beam semiconductor inspection system or an electron beam semiconductor review system.

The gap may be a dimension from 0.5 mm to 0.55 mm.

The electron beam source may include a tip with a radius from 0.3 μm to 1 μm.

A method is provided in a second embodiment. The method includes generating an electron beam with an electron beam source. The electron beam is directed toward a workpiece through an objective lens. The objective lens includes a pole piece that defines a gap along a path of the electron beam. Secondary electrons and back-scattered electrons emitted from the workpiece are collected at a detector.

The workpiece may be a semiconductor wafer.

The pole piece may be an inner pole piece of the objective lens.

The pole piece may be a split lens.

The pole piece may be configured to collimate a majority of the secondary electrons to a center channel of the detector. In an example, >95% of the secondary electrons are directed at the center channel.

The pole piece may be configured to collect more of the back-scattered electrons on a side channel of the detector than the secondary electrons.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of an embodiment of an electron beam system in accordance with the present disclosure;

FIG. 2 shows a magnetic peak for the objective lens in FIG. 1 with a comparison of the electron beam received by the detector;

FIG. 3 shows a comparison between a split lens and an existing lens, which shows that the split lens has a smaller magnification to the secondary beam;

FIG. 4 shows how a split lens can reduce demagnification;

FIG. 5 shows results of simulations of lens, gun tip, and column TC cancellations; and

FIG. 6 is a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments of the present disclosure improve image quality (IQ) of an electron beam system with respect to topography, uniformity, and charging control. More large-launching-angle electrons are collected and segmented to improve topography. Electron cloud displacement on the detector is reduced while scanning the primary beam, which can improve image uniformity. Secondary electrons are reduced on segmented channel while increasing back-scattered electrons on segmented channels, which can improve charging control. Charging control refers to making an image more resistant to charging. Here, secondary electrons have lower energy and are more sensitive to charging. Thus, changing the imaging component from low energy secondary electrons to high energy back-scattered electrons improves image charging. The system can include a split objective lens, a transverse chromatic (TC) cancellation column, and an optimized gun tip size.

A split lens concept cut a 0.5 mm slit on the inner pole piece, which generates a secondary magnetic field. This secondary magnetic field can collimate the secondary electron/back-scattered electron beam more to the BLDF detector. Thus, more large-launching-angle signal electrons can be collected by the segmented side channels of the BLDF detector. The split lens enlarges transverse chromatic blur, so transverse chromatic reduction technology can be applied. A split lens may extend the spot size slightly, which can be compensated by gun tip size optimization.

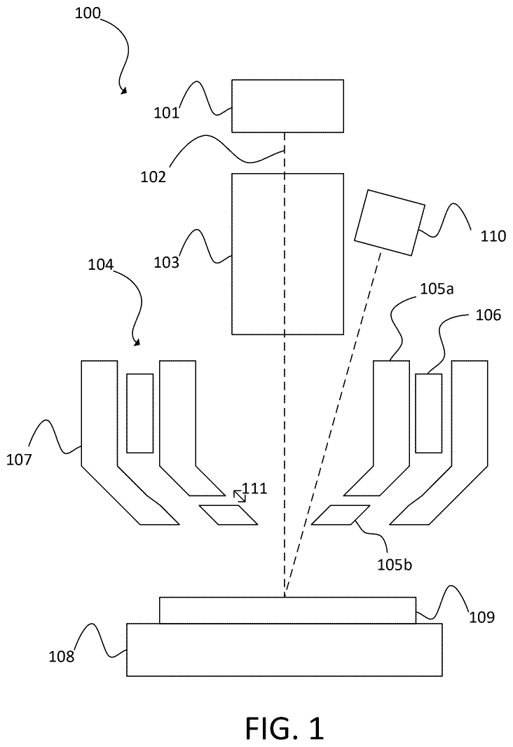

FIG. 1 is a diagram of an embodiment of an electron beam system 100. The system includes an electron beam source 101 that generates an electron beam 102 (shown with dotted line). The electron beam system 100 also includes other optical components 103 along the path of the electron beam 102. These optical components can include, for example, a Wien filter, gun lens, anode, beam limiting aperture, gate valve, a beam current selection aperture, scanning subsystem, electrodes, lenses, vacuum valve, deflector, or condenser lens.

A stage 108 holds a workpiece 109 (e.g., a semiconductor wafer) in a path of the electron beam 102. Some or all of the secondary electrons and back-scattered electrons are emitted from the workpiece 109 and are received by the detector 110.

The objective lens 104 is disposed along the path of the electron beam 102. The electron beam 102 passes through the objective lens 104. The secondary electrons and back-scattered electrons in the electron beam 102 emitted from the workpiece 109 also pass through the objective lens 104. The objective lens 104 includes an inner pole piece 105a-105b, an objective lens coil 106, and an outer pole piece 107. In an instance, the objective lens coils 106 may be fabricated of non-magnetic material. The inner pole pieces 105a-105b may wrap around all sides of the electron beam 102 (i.e., extend into and out of the page). The inner pole pieces 105a-105b include a gap between the inner pole piece 105a and inner pole piece 105b, which is represented by the arrow 111. The gap may be from approximately 0.45 to 0.55 mm in length, such as from approximately 0.5 to 0.55 mm. In an instance, the gap is approximately 0.5 mm. The gap is positioned along the path of the electron beam 102. Thus, the inner pole piece 105a-105b make a split lens. The inner pole piece 105a-105b are configured to collimate a majority of the secondary electrons (e.g., >95%) to a center channel of the detector 110 and collect the back-scattered electrons (e.g., >30%) on a side channel of the detector 110. Thus, more of the back-scattered electrons are collected on a side channel of the detector 110 than secondary electrons. In an instance, a majority of the back-scattered electrons are collected on a side channel of the detector 110.

The location of the gap between inner pole pieces 105a-105b shown by arrow 111 can affect the electron beam 102. The location of this gap and the relative heights of the inner pole pieces 105a-105b can be configured to compromise between collection efficiency and resolution. However, the position of the gap may depend on the objective lens design, energy of electrons, detector locations, or other variables. In an embodiment, the gap may be more proximate to the side of the inner pole pieces 105a-105b facing the workpiece 109 than the optics 103 upstream of the inner pole pieces 105a-105b. In an embodiment, only the inner pole pieces 105a-105b include the gap. The outer pole piece 107 does not include a gap.

The split lens can improve image quality. Dividing the inner pole pieces 105a-105b of objective lens 104 to include a gap will leak a second magnetic field. In an instance, this second magnetic field may be 15 mm from the bottom of the inner pole piece 105b and may be approximately one-tenth the strength of the primary peak. Through adjusting the position and dimension of the gap in the inner pole pieces 105a-105b, this second magnetic field can collimate the secondary electrons more to the BLDF center channel of the detector 110 and collect more dark field back-scattered electrons on the side channel of the detector 110. This can change the signal distribution on the detector 110. For example, fewer secondary electrons may be directed to the side channels and as many back-scattered electrons may be directed to the side channels as possible. The signal distribution may be configured to account for factors such as resolution degrade or chromatic coefficient increase. SEM image grey level variation includes material contrast and surface topography contrast. Secondary electrons provide mostly material contrast whereas back-scattered electrons provide mostly topographic contrast. Therefore, separating secondary electrons and back-scattered electrons will provide more accurate information about the observed target. Less secondary electrons on the side channel also may make the image more resistant to charging. The dark field back-scattered electrons can provide higher topographical contrast. The electronic properties of the objective lens 104 may remain the same as an existing objective lens without the gap.

The electron beam system 100 may be part of an electron beam semiconductor inspection system or an electron beam semiconductor review system. The inspection system can be used to find defects on the workpiece 109. The review system can evaluate sites on the workpiece 109 that were flagged as potential defects.

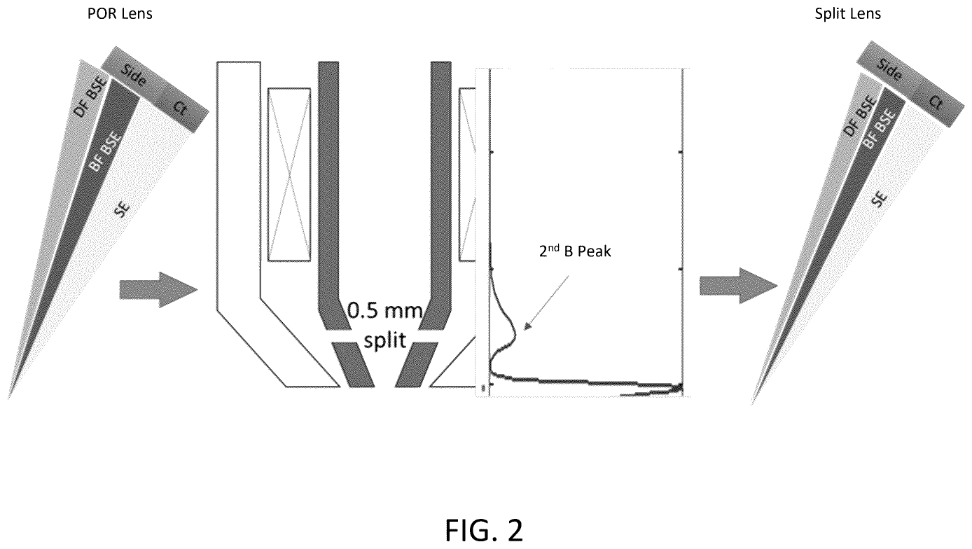

FIG. 2 shows a magnetic peak for the objective lens 104 in FIG. 1 with a comparison of the electron beam received by the detector 110. As shown in FIG. 2, a second magnetic peak (“2nd B peak”) can focus the primary beam. FIG. 2 compares a signal distribution of an existing process of record (POR) lens and the split lens shown in FIG. 1 or FIG. 2. The POR lens has secondary electrons on the center (ct) and side channel (side). The bright field (BF) back-scattered electrons and dark field (DF) back-scattered electrons are directed at the side channel, but some dark field back-scattered electrons are not collected. With the split lens, secondary electrons are primarily or only directed at the center channel. The bright field back-scattered electrons and dark field back-scattered electrons are primarily or only directed at the side channel.

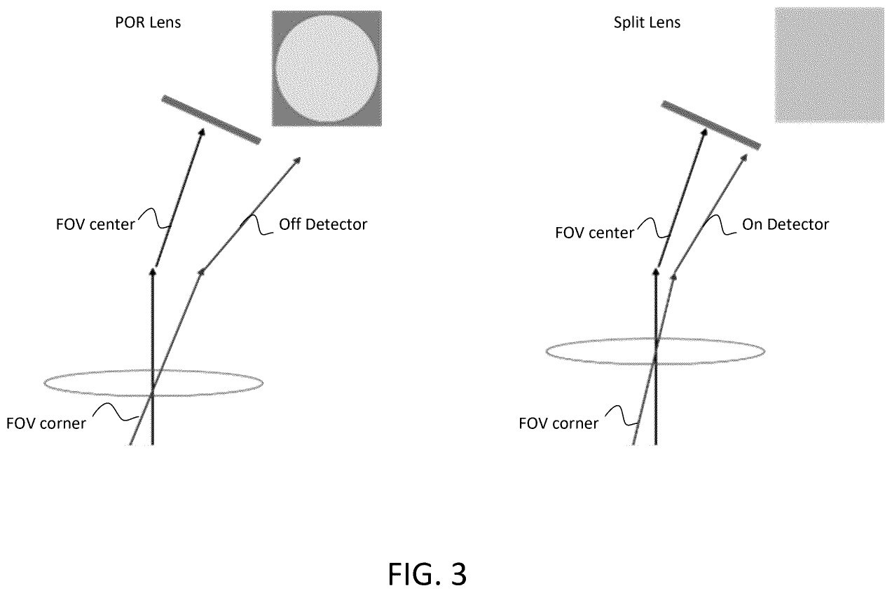

Another advantage of larger field of view (FOV) is that the second magnetic peak focuses the primary beam earlier than the existing lens, which is equivalent to a lift of the lens center. This results in less sensitivity from workpiece 109 plane to detector 110 plane. That same offset on the workpiece 109 (FOV corner to center) will cause less signal cloud displacement on the detector 110. When the FOV is larger than some limit, the signal from FOV corner could miss the detector 110 and the image may have a dark corner. This FOV limitation is extended by the split lens in the objective lens 104. Thus, split lens images are more uniform. FIG. 3 shows a comparison between a split lens (e.g., the objective lens 104) and an existing lens (POR), which shows that the split lens has a smaller magnification to the secondary beam from workpiece 109 plane to detector 110 plane, resulting in less signal cloud offset when the primary beam is scanned in FOV. This can provide a larger FOV without dark corners. Directing more of the beam onto the detector can reduce or eliminate dark corners, which is shown in the results of FIG. 3. Off detector beams can result in the dark corners shown on the left of FIG. 3.

The objective lens 104 may provide enlarged transverse chromatic aberration. Transverse chromatic aberration may be caused by a Wien filter in the optical components 103. The energy spread can be translated to a transverse angle dispersion and finally to a chirped spot along a specific direction. Chirped refers to extending and lowering the intensity. It is normally provided by electron optics simulations. It also can be interpreted in that the split lens lifts the lens center. When electrons with dispersed angles pass through the split lens, beam size is still small, and the beam cannot be focused as strongly as in the existing lens. Thus, the final chirping is larger. By tilting a column (or at least some of the components of the column) at a correct angle, Wien filter induced transverse chromatic cancellation may become negligible.

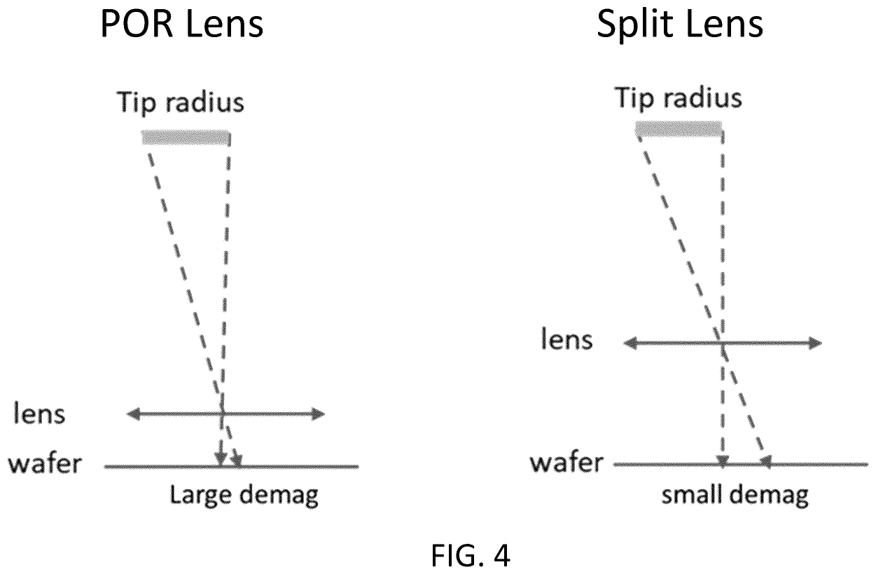

FIG. 4 shows how a split lens can reduce demagnification. The beam path is simplified. The objective lens may be used for focusing. FIG. 3 shows that the raised lens center has smaller magnification to the secondary beam. Similarly, the demagnification of the primary beam from gun tip to the workpiece 109 is reduced as illustrated in FIG. 4. A smaller virtual tip size can compensate for reduced demagnification. Resolution can be defined using the following formula.

$$r es = \sqrt{{( demag * tip\_size )}^{2} + {sph}^{2} + difr {.}^{2} + A {C}^{2} + T {C}^{2} + {COMA}^{2} + …}$$

In the formula, res is beam resolution, demag is system demagnification, tip_size is the virtual size of gun tip, sph is the spherical aberration, difr is the diffraction aberration, AC is the on-axis chromatic aberration, TC is transverse chromatic aberration, and COMA is coma aberration. With smaller gun tip size, the first item in the resolution formula, which is noted as a Gaussian term, can be maintained or even improved. However, a smaller tip size may result in a larger energy spread. Thus, the AC and TC terms are expected to be worse. The TC term could be mostly compensated by TC cancelation technologies discussed herein.

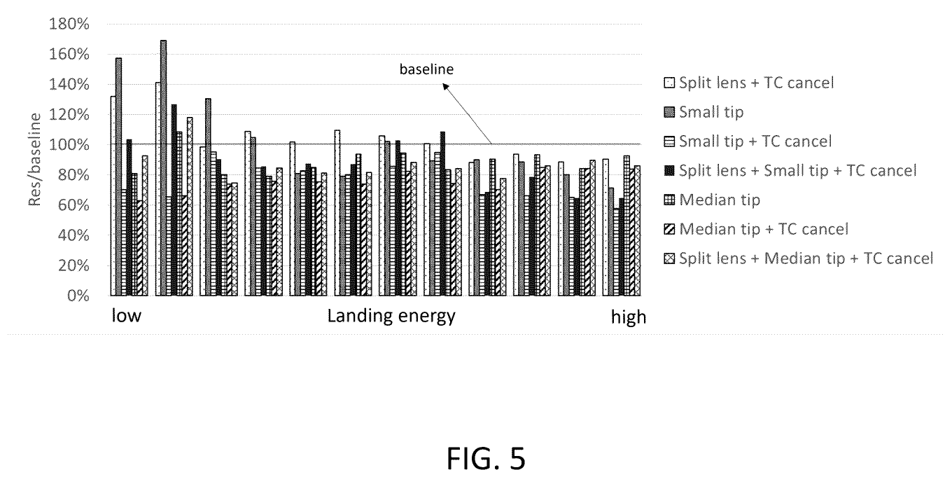

Munro simulations were conducted to different technology options and different beams. FIG. 5 shows results of simulations of lens, gun tip, and column TC cancellations for different feature combinations. The results indicate that tip size optimization can compensate for the impact of the split lens on electron beam resolution. The left bar in each set show that a split lens and TC cancelation will have half the beams with worse resolution. The second bar from the left in each set shows that a smaller tip will benefit most of beams to become better than baseline. The bar on the right of each set is an optimized trade-off between the tip size and energy spread, which predicts better resolution for low landing energies and sacrifices a little of high landing energies to further improve the resolution.

A prototype was fabricated with a split lens, gun with smaller tip size, and 1.7-degree tilted column above the Wien filter to reduce TC. A smaller tip size means that the tip is sharper and has a smaller radius. The smaller radius may be from approximately 0.3 μm to 1 μm. Different semiconductor wafers were tested. A prototype of the system 100 showed that the split lens can provide larger FOV, better topography and charging resistance, and compensate for the disadvantages of larger TC and smaller demagnification. Thus, the sharpness and sensitivity are both enhanced.

With the prototype of the system 100, the split lens provided larger FOV with good uniformity. Compared to an existing process of record system, the split lens enhanced topography on the surface of the workpiece and eliminated artificial shading. The split lens had better charging control to avoid non-uniformity in small FOV of 6 μm. The reduced tip size and tilted beam trajectory provided better sharpness to compensate the split lens disadvantages. A sensitivity comparison on a topographic defect on a bare wafer showed that the system 100 is more sensitive with less frame average and less pixel density.

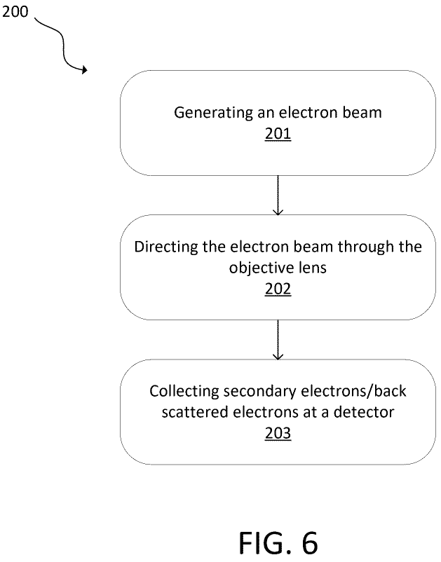

FIG. 6 is a flowchart of a method 200. The method 200 can use an embodiment of the electron beam system 100. At 201, an electron beam is generated and directed toward a workpiece (e.g., a semiconductor wafer). The electron beam is directed through an objective lens at 201. The pole piece may be a split lens. The objective lens includes a pole piece that defines a gap along the path of the electron beam. At 203, secondary electrons and back-scattered electrons from the workpiece are collected at a detector. The pole piece can be configured to collimate a majority of the secondary electrons to a center channel of the detector. The pole piece also can be configured to collect a majority of the back-scattered electrons on a side channel of the detector.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron beam source that generates an electron beam;
a stage configured to hold a workpiece in a path of the electron beam;
a detector that receives secondary electrons and back-scattered electrons emitted from the workpiece on the stage; and
an objective lens disposed in the path of the electron beam, wherein the objective lens includes an inner pole piece, an outer pole piece, and a coil between the inner pole piece and the outer pole piece, and wherein the inner pole piece defines a gap along the path of the electron beam.

2. The system of claim 1, wherein the inner pole piece is a split lens.

3. The system of claim 1, wherein the inner pole piece is configured to collimate a majority of the secondary electrons to a center channel of the detector.

4. The system of claim 3, wherein >95% of the secondary electrons are directed at the center channel.

5. The system of claim 1, wherein the inner pole piece is configured to collect more of the back-scattered electrons on a side channel of the detector than the secondary electrons.

6. The system of claim 1, wherein the system is an electron beam semiconductor inspection system.

7. The system of claim 1, wherein the system is an electron beam semiconductor review system.

8. The system of claim 1, wherein the gap has a dimension from 0.5 mm to 0.55 mm.

9. The system of claim 1, wherein the electron beam source includes a tip with a radius from 0.3 μm to 1 μm.

10. A method comprising:
generating an electron beam with an electron beam source;
directing the electron beam toward a workpiece through an objective lens, wherein the objective lens includes a pole piece, and wherein the pole piece defines a gap along a path of the electron beam; and
collecting secondary electrons and back-scattered electrons emitted from the workpiece at a detector.

11. The method of claim 10, wherein the workpiece is a semiconductor wafer.

12. The method of claim 10, wherein the pole piece is an inner pole piece of the objective lens.

13. The method of claim 10, wherein the pole piece is a split lens.

14. The method of claim 10, wherein the pole piece is configured to collimate a majority of the secondary electrons to a center channel of the detector.

15. The method of claim 14, wherein >95% of the secondary electrons are directed at the center channel.

16. The method of claim 10, wherein the pole piece is configured to collect more of the back-scattered electrons on a side channel of the detector than the secondary electrons.
